(19) United States
(12) Patent Application Publication
(10) Pub. No.: US 2012/0298199 A1
(43) Pub. Date: Nov. 29, 2012

(54) SOLAR CELL AND MANUFACTURING METHOD THEREOF

(75) Inventors: Jinfeng Kang, Beijing (CN); Bao Wang, Beijing (CN); Xu Wang, Beijing (CN); Tianshu Zhang, Beijing (CN); Ziqing Lu, Beijing (CN); Yan Wang, Beijing (CN); Xiaoyan Liu, Beijing (CN)

(73) Assignee: PEKING UNIVERSITY, Beijing (CN)

(21) Appl. No.: 13/116,779

(22) Filed: May 26, 2011

(51) Int. Cl. H01L 31/0296; H01L 31/18

(52) U.S. Cl. 136/258; 438/64; 257/E31.015

(57) ABSTRACT

A solar cell includes a cathode component, an anode component, sealant for assembling the cathode component and the anode component to form a closed space, and electrolyte accommodated in the closed space, in which the cathode component contains a lower transparent conductive substrate, a nano-oxide semiconductor thin film formed on the lower transparent conductive substrate, and dye attached to a nano-particle surface of the nano-oxide semiconductor thin film; and the anode component contains an upper transparent conductive substrate, and an anode electrode layer formed on the upper transparent conductive substrate, the nano-oxide semiconductor thin film and the anode electrode layer being arranged opposite to each other and contacting with the electrolyte, in which the anode component further contains a CdTe layer which is patterned to have an opening, and the anode electrode layer is located in the opening of the CdTe layer.

### BACKGROUND OF THE INVENTION

1. Field of Invention

The present invention relates to a solar cell and a manufacturing method thereof, and particularly to a dye-sensitized solar cell (DSSC) and a manufacturing method thereof.

2. Description of Prior Art

A French scientist Henri Becqμerel first observed in 1839 a photoelectric conversion phenomenon. But until 1954, a first practical semiconductor solar cell came out, which made an idea of “Solar Energy into Electric Energy” really come to a reality. In an initial development stage of the solar cell, materials to be used generally were a narrow band gap semiconductor material which has a certain absorption in a visible region. Thus, this kind of solar cell may also be known as a semiconductor solar cell.

Although a wide bandgap semiconductor material has a poor capability of capturing sunlight, an appropriate dye may be attached to a surface of the semiconductor, so that the solar energy may also be converted into the electric energy by means of a strong absorption of the dye to visible light. This kind of cell is the dye-sensitized solar cell.

The dye-sensitized solar cell is a novel photochemical solar cell as proposed in 1991 by a Swiss scientist professor Grätzel. A fundamental structure of the dye-sensitized solar cell is formed by a cathode consisting of TiO₂ nano-particles, electrolyte containing an I⁻/I⁻₃ redox couple, and an anode containing a catalyst layer. The efficiency of the novel dye-sensitized solar cell based on the Grätzel cell has reached 11%, which has a good application prospect.

With irradiation of monochromatic light having a wavelength λ, photoelectric conversion efficiency of a thin film solar cell may be determined by a formula as follows:

E_{ff}(λ)=LHE(λ)φᵢₙⱼη_{c}

wherein LHE (λ) is a ratio of light intensity as absorbed by the dye to a total light intensity of incident light, which is mainly dependent on a property of the dye and the amount of the dye absorbed in the thin film; φᵢₙⱼ is a quantum efficiency, i.e. a probability that excited electrons of the dye are injected into an oxide conduction band; and η_{c} is a collection efficiency, i.e. a probability that the electrons in the conduction band reach the cathode through the oxide film.

According to the above formula, a nano-porous thin film which plays a role of receiving and transmitting electrons in the thin film solar cell may satisfy at least the following three conditions:

(1) the nano-porous thin film must have a sufficiently large specific surface area, so that a great amount of dye may be absorbed;

(2) approaches of absorbing the dye by the nano-porous thin film must guarantee that the electrons may be injected into the conduction band of the thin film efficiently;

(3) in the nano-porous thin film, the electrons may have a fast transfer rate, so as to reduce recombination of the electrons with a electrolyte acceptor.

For the above three conditions, it has been proposed that the nano-porous oxide semiconductor thin film such as Fe₂O₃, CdS, SnO₂ may be used as the cathode of the DSSC. However, the effect is not very ideal.

A main reason why the photoelectric conversion efficiency of the DSSC is relatively low is that the third condition cannot be satisfied. In other words, the electrons in the thin film may be recaptured with the electrolyte acceptor, and thus the transmission of the electrons is cut off.

Another reason for the lower photoelectric conversion efficiency of the DSSC is that an absorption spectrum of the dye does not match with a solar emission spectrum of the sun. In other words, most of energy in the solar spectrum cannot be effectively used in the traditional DSSC.

### SUMMARY OF THE INVENTION

Accordingly, one object of the present invention is to provide a dye-sensitized solar cell which may efficiently improve photoelectric conversion efficiency.

According to one aspect of the present invention, a solar cell is provided. The solar cell comprises a cathode component, an anode component, sealant for assembling the cathode component and the anode component to form a closed space, and electrolyte accommodated in the closed space, wherein the cathode component comprises a lower transparent conductive substrate, a nano-oxide semiconductor thin film formed on the lower transparent conductive substrate, and dye attached to a nano-particle surface of the nano-oxide semiconductor thin film; and the anode component comprises an upper transparent conductive substrate, and an anode electrode layer formed on the upper transparent conductive substrate, the nano-oxide semiconductor thin film and the anode electrode layer being arranged opposite to each other and contacting with the electrolyte, wherein the anode component further comprises a CdTe layer which is patterned to have an opening, and the anode electrode layer is located in the opening of the CdTe layer.

Preferably, in the solar cell, the nano-oxide semiconductor thin film comprises a first nano-oxide semiconductor layer and a second nano-oxide semiconductor layer on the first nano-oxide semiconductor layer, the second nano-oxide semiconductor layer and the anode electrode layer being arranged opposite to each other, a radius of the nano-particle in the second nano-oxide semiconductor layer being larger than that in the first nano-oxide semiconductor layer.

Preferably, in the solar cell, the nano-oxide semiconductor thin film is made from one selected from the group consisting of TiO₂, ZnO, SnO₂, Nb₂O₅.

Preferably, in the solar cell, a thickness of the nano-oxide semiconductor thin film is 1.0-2.0 μm.

Preferably, in the solar cell, the radius of the nano-particle in the nano-oxide semiconductor thin film is 80-120 nm.

Preferably, in the solar cell, the anode electrode layer is made from one selected from the group consisting of platinum, and graphene.

Preferably in the solar cell, a thickness of the anode electrode layer is 0.2-0.5 μm.

Preferably in the solar cell, the CdTe layer has a shape of a stripe or a grid.

Preferably in the solar cells, the opening in the CdTe layer has a shape of square, rectangle, round, or hexagon.

According to another aspect of the present invention, a method of manufacturing a solar cell is provided. The method comprises steps of:

a) forming a cathode component, the cathode component comprising a lower transparent conductive substrate, a nano-oxide semiconductor thin film formed on the lower transparent conductive substrate, and dye attached to a nano-particle surface of the nano-oxide semiconductor thin film;

b) forming an anode component, the anode component comprising an upper transparent conductive substrate, and an anode electrode layer and a CdTe layer formed on the upper transparent conductive substrate; and

c) assembling the cathode component and the anode component by using sealant to form a closed space; injecting electrolyte into the closed space, so that the nano-oxide semiconductor thin film and the anode electrode layer are arranged opposite to each other and contact with the electrolyte.

Wherein the step b) of forming the anode component comprises: patterning the

CdTe layer to have an opening; and filing the opening with the anode electrode layer.

Preferably in the method, the step of patterning the CdTe layer to have the opening comprises: depositing the CdTe layer, planarizing the CdTe layer, and etching the CdTe layer to form the opening.

Preferably in the method, the CdTe layer is formed by sputtering, evaporating or electrodepositing in the step of depositing the CdTe layer.

Preferably in the method, the step of filling the opening with the anode electrode layer comprises: depositing the anode electrode layer in the opening of the CdTe layer from an opening portion of a shielding mask by using the shielding mask aligned with the opening.

Preferably in the method, the step of filling the opening with the anode electrode layer comprises: forming the anode electrode layer in the opening of the CdTe layer by screen printing.

Preferably in the method, the step of forming a first nano-oxide semiconductor layer comprises: producing nano-TiO₂ paste by a sol-gel method; printing the nano-TiO₂ paste on a transparent conductive substrate; and baking.

Preferably in the method, the step of forming a second nano-oxide semiconductor layer comprises: producing nano-TiO₂ paste using TiO₂ particles; printing the nano-TiO₂ paste on a transparent conductive substrate; and baking.

Preferably in the method, the CdTe layer has a shape of a stripe or a grid.

Preferably in the method, the opening in the CdTe layer has a shape of square, rectangle, round, or hexagon.

In the solar cell of the present invention, the sunlight passes through the nano-oxide semiconductor thin film, and a part of the sunlight is absorbed and then further propagated to the anode component. Since an entire surface of the patterned CdTe layer is not covered with the anode electrode layer, the CdTe layer may absorb the sunlight efficiently. Moreover, the CdTe layer may absorb light in a long-wave band which cannot be absorbed by the dye. Thus, the absorption spectra of the dye-sensitized solar cell may be expanded, which may achieve an optimal match between the absorption spectrum of the solar cell and the solar spectrum, and improve the absorption rate of the solar cell to the sunlight.

A large number of electrons may be excited by the CdTe layer and may be provided to the electrolyte, so that an exchanging rate of the redox electron pairs in the electrolyte is increased, and charge loss due to recombination of the electrons already excited to the TiO₂ conduction band with the electrolyte is efficiently reduced. Thus, the conversion efficiency of the DSSC and a current density may be improved efficiently. Moreover, it may also affect an energy level of the electrolyte, and improve an open circuit voltage, which is equivalent to an “amplification” of original DSSC photocurrent by a newly formed CdTe layer.

When the solar cell of the present invention operates, a self-built potential may be generated inside the solar cell, so as to accelerate transmission of the electrons from the anode to the cathode.

Accordingly, compared with the traditional single DSSC, the DSSC of the present invention significantly suppresses occurrence of a dark reaction, increases the photocurrent density, open circuit voltage, and the utilization of the sunlight, based on enhancement of dye-sensitized reactions. Thus, the photoelectric conversion efficiency may be effectively improved.

### BRIEF DESCRIPTION OF THE DRAWINGS

FIG. 1 shows a schematic diagram of an anode component in a DSSC according to the present invention;

FIG. 2 shows a schematic diagram of a DSSC according to a first embodiment of the present invention;

FIG. 3 shows a schematic diagram of a DSSC according to a second embodiment of the present invention; and

FIG. 4 shows an energy band schematic diagram according to an operating principle of a DSSC of the present invention.

### DETAILED DESCRIPTION OF PREFERRED EMBODIMENTS

The embodiments of the present invention will be described below in detail by referring to the attached drawings. The same or similar reference signs are used for denoting the same or similar elements throughout the attached drawings. The embodiments are only illustrative and only used for explaining the present invention, but is not construed to limit the present invention.

FIG. 1 shows a schematic diagram of an anode component in a DSSC according to the present invention. The anode component comprises a transparent conductive substrate 11, a CdTe layer 12 on the transparent conductive substrate 11, and an anode electrode layer 13 (e.g. platinum) located in an opening of the CdTe layer 12. The CdTe layer 12 is a polycrystalline film, the thickness of which is 1-2.0 μm. Preferably, the thickness of the CdTe layer 12 is 1.5 μm. A particle diameter of CdTe in the CdTe layer 12 is 90-120 nm. Preferably, the particle diameter of CdTe in the CdTe layer 12 is 100 nm. The thickness of the anode electrode layer 13 is 0.2-0.5 μm. Preferably, the thickness of the anode electrode layer 13 is 0.2 μm.

The CdTe layer as shown in FIG. 1 is has a shape of a stripe. However, the CdTe layer may also have a shape of a grid, as long as it has an opening exposing the transparent conductive substrate 11. The opening in the CdTe layer may have a shape of square, rectangle, round, or hexagon.

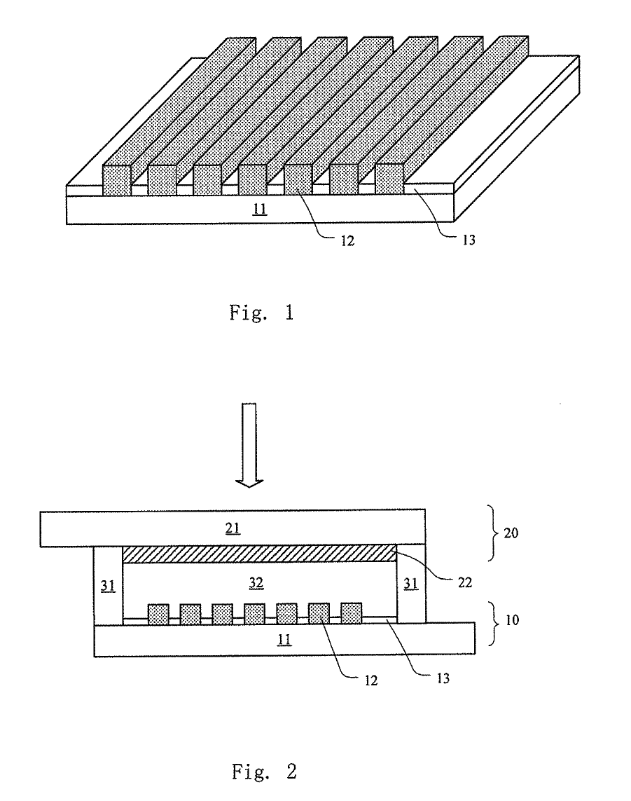

FIG. 2 shows a schematic diagram of a DSSC according to a first embodiment of the present invention, wherein the anode component 10 as shown in FIG. 1 has been assembled with the cathode component 20, which will be described below. The solar cell comprises the anode component 10, the cathode component 20, sealant 31 for assembling the anode component 10 and the cathode component 20 to form a closed space, and electrolyte 32 accommodated in the closed space. The anode component 10 comprises the upper transparent conductive substrate 11, and the anode electrode layer 13 formed on the upper transparent conductive substrate 11, the nano-oxide semiconductor thin film 22 and the anode electrode layer 13 may be arranged opposite to each other and contact with the electrolyte 32, wherein the anode component 10 further comprises the CdTe layer 12 which is patterned to have an opening, and the anode electrode layer 13 is located in the opening of the CdTe layer 12. The cathode component 20 comprises a lower transparent conductive substrate 21, a nano-oxide semiconductor thin film 22 formed on the lower transparent conductive substrate 21, and dye (not shown) attached to a nano-particle surface of the nano-oxide semiconductor thin film 22.

In the solar cell, the nano-oxide semiconductor thin film 22 may consist of a n-type wide bandgap semiconductor, such as TiO₂, ZnO, SnO₂, Nb₂O₅.

In the solar cell, the thickness of the nano-oxide semiconductor thin film is 1.0-2.0 μm.

In the solar cell, the radius of the nano-particle in the nano-oxide semiconductor thin film is 80-120 nm.

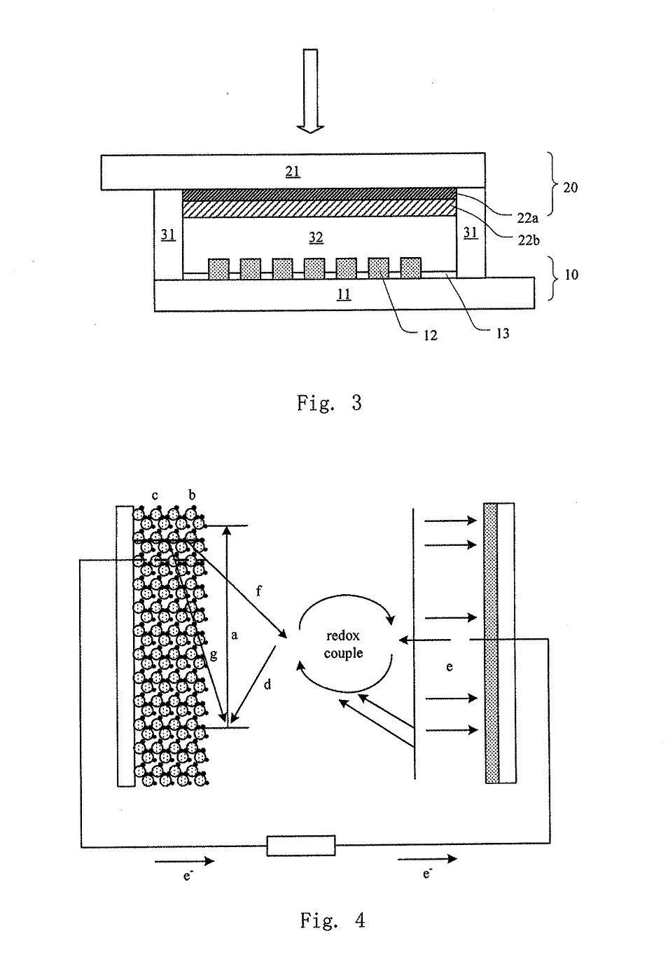

FIG. 3 shows a schematic diagram of a DSSC according to a second embodiment of the present invention. The structure of the solar cell is similar with that as shown in FIG. 2. The only difference consists in that the nano-oxide semiconductor thin film 22 is constituted of two layers of nano-particles with different sizes. As shown in FIG. 3, the nano-oxide semiconductor thin film 22 comprises a first nano-oxide semiconductor layer 22a and a second nano-oxide semiconductor layer 22b on the first nano-oxide semiconductor layer 22a. The second nano-oxide semiconductor layer 22b and the anode electrode layer 13 may be arranged opposite to each other. The radius of the nano-particle in the second nano-oxide semiconductor layer 22 is larger than that in the first nano-oxide semiconductor layer.

The nano-oxide semiconductor thin film 22 consisting of the first nano-oxide semiconductor layer 22a and the second nano-oxide semiconductor layer 22b which have different nano-particle radii may be used for further enhancing the light absorption effect of the dye, so as to improve the photoelectric conversion efficiency.

Hereinafter, various steps in the method of the DSSC manufacture according to the present invention will be described in detail.

First, the CdTe layer 12 may be deposited on the transparent conductive substrate 11 by LPCVD (Low Pressure Chemical Vapor Deposition). After the CdTe layer 12 is formed, a chemical mechanical polishing (CMP) may be performed on the as-deposited CdTe layer 12 which has an uneven surface, and an actual thickness of the CdTe layer 12 is decreased to 1.5 μm.

Next, the CdTe layer 12 is subjected to a lithography process. A grid structure is provided in the CdTe layer 12 by highly conformal reactive ion etching (RIE). Taking a 5 cm×5 cm DSSC as an example in this embodiment, the CdTe layer 12 has a pitch of 1.5 mm.

Finally, the anode electrode layer 13 may be screen printed on the CdTe layer 12. Alternatively, the shielding mask (not shown) aligned with the opening may be used, and the anode electrode layer 13 may be sputtered in the opening of the CdTe layer from the opening portion of the shielding mask. The thickness of the anode electrode layer 13 is 0.2 μm. Then, the manufacture of the anode component 10 is completed.

Next, the cathode component 20 as shown in FIG. 3 is prepared, which comprises a step of applying a small-particle nano-TiO₂ paste and a step of applying a large-particle nano-TiO₂ paste on the transparent conductive substrate 21.

First, the transparent conductive substrate 21 is cleaned in an ultrasonic cleaning bath and dried after the cleaning.

The small-particle nano-TiO₂ paste may be prepared as follows. The sol-gel process may be used for preparing the nano-TiO₂ paste. A 50 mL of 0.2 mol/L triethylamine solution and 250 mL of 0.1 mol/L titanium acetate solution are prepared. With stirring at a rate of the 120 r/min-180 r/min, the triethylamine solution may be added to the titanium acetate solution. In order to make the TiO₂ particles uniform and to prevent the particles from quickly aggregating, the triethylamine solution may be slowly added to the titanium acetate solution with a dropping funnel. With the addition of the triethylamine solution, white floccule may be formed. Continuing stirring, it becomes to stable sol after 15 h or so. Then, a 600 MM strainer may be used for filtering, so as to remove the large-grain TiO₂. The sol may be placed into a high-speed refrigerated centrifuge for a centrifugal processing to obtain white TiO2 precipitation, and the white precipitation may be cleaned with deionized water and pure alcohol for several times. In order to increase a specific surface area of the thin film and to prevent cracking occurred during sintering, 10-20 ml polyethylene glycol may be added to the TiO₂ precipitation as a surfactant, and may be stirred uniformly. Finally, it may be rotated in a high vacuum for removing water by evaporation, and the required small-particle nano-TiO₂ paste may be obtained after grinding.

The large-particle nano-TiO₂ paste may be prepared as follows. 6 g of commercial TiO₂ P25 particles produced by a German company Degussa may be mixed with 1 ml acetic acid, and may be ground in a mortar for 5 minutes. Then, 1 ml deionized water may be added into the mortar followed by grinding for 1 minute, which may be repeated for 5 times. Then, 1 ml ethanol may be added followed by grinding for 1 minute, which may be repeated for 15 times. Then, 2.5 ml ethanol may be added followed by grinding for 1 minute, which may be repeated for 6 times. After all of the above grinding works are completed, the TiO₂ in the mortar may be transferred to a large beaker, into which 100 ml ethanol may be added. The beaker may be put on a magnetic mixing machine and be stirred for 2 minutes. Then, 20 g terpineol may be added into the beaker, and continue to be stirred for 2 minutes on a magnetic mixing machine. Then, ethyl cellulose may be added, and dissolved in the ethanol solution, with a ratio of 3 g ethyl cellulose: 30 g of total amount of ethanol added in this embodiment, and stirred for 6 minutes by the magnetic mixing machine. Finally, the large-particle TiO₂ paste may be prepared after evaporating the ethanol in the breaker out on the rotary evaporator.

Next, the transparent conductive substrate 21 may be put on the screen printer, so that the nano-TiO₂ paste may be printed on the transparent conductive substrate 21. The transparent conductive substrate 21 with the printed TiO₂ may be put on an electrical hot plate and baked for 10 minutes. The temperature may be set to be 80□, so that the solvent may be evaporated slowly, and thus the first nano-oxide semiconductor layer 22a may be formed. It may be observed by a scanning electric microscope that the nano-TiO₂ in the first nano-oxide semiconductor layer 22a may be spherical substantially with an average radius 25 nm. The thickness of the first nano-oxide semiconductor layer 22a as measured by a surface profiler is 2.4 μm.

Next, the transparent conductive substrate 21 with the first nano-oxide semiconductor layer 22a may be put on the screen printer again, so that the prepared large-particle nano-TiO₂ paste may be printed on the first nano-oxide semiconductor layer 22a. The transparent conductive substrate 21 with the printed TiO₂ may be put on an electrical hot plate and baked for 10 minutes. The temperature may be set to be 80□, so that the solvent may be evaporated slowly. Then the transparent conductive substrate 21 with the printed TiO₂ may be put in a Muffle furnace and baked for one hour. The temperature may be set to be 450° C., thus the second nano-oxide semiconductor layer 22b may be formed. It may be observed by a scanning electric microscope that the nano-TiO₂ in the second nano-oxide semiconductor layer 22b may be spherical substantially with an average radius 80 nm. The thickness of the second nano-oxide semiconductor layer 22b as measured by a surface profiler is 4.6 μm.

Further, the anode component 10 and the cathode component 20 may be assembled together to form the solar cell according to the following steps.

The sealant 31 may be used for assembling the anode component 10 and the cathode component 20 together. The second nano-oxide semiconductor layer 22b and the anode electrode layer 13 may be arranged opposite to each other to form the closed space. The electrolyte 32 (e.g. electrolyte solution or solid electrolyte) may be injected into the closed space.

The assembled solar cell is shown in FIG. 3. the CdTe layer 12 and the anode electrode layer 13 in the anode component 10 and the first nano-oxide semiconductor layer 22a and the second nano-oxide semiconductor layer 22b in the cathode component 20 may contact with the electrolyte 32. The CdTe layer 12 may be used as the electron injection layer of the DSSC, and may inject photoelectron current into the electrolyte 32 when irradiated by the sunlight.

The above transparent conductive substrates 11 and 21 may be e.g. FTO (fluorine (F)-doped tin oxide) conductive glass commercially available from the Japanese Nippon Sheet Glass Company. The nano-oxide particles may be commercially available in the market, such as the commercial P25 TiO₂ particles produced by the Germany Degussa company. The dye may be commercially available in the market, such as N3 dye produced by Qi Se Guang company in Da Lian, China.

FIG. 4 shows an energy band schematic diagram according to the operating principle of a DSSC of the present invention. The left of the drawing is cathode, and the right of the drawing is anode, wherein b) the electrons exited by absorbing photons by the dye S may be directly injected into the conduction band of the nano-porous oxide semiconductor; c) the electrons may be transported from the TiO₂ conduction band to the cathode, and absorbed by the cathode; d) oxidized dye molecules may be deoxidized by the redox couple. The processes as shown by two lines of f) and g) may be referred to as electron recombination or interception, which is the main reason for the low efficiency of the DSSC. Particularly, the process as shown in f) is commonly considered as the most important factor for failing to further improve the DSSC efficiency, in which the electrons injected into the TiO2 conduction band are recaptured by iodines. The innovation of this invention consists in that the thin film solar cell structure is introduced, and an excellent light excitation characteristic of the thin film solar cell may be utilized to generate the electrons for complementing the requirements of the electrolyte redox couple for the electrons. Thus, the f) process may be suppressed, and the d) process may be accelerated. Additionally, as shown in FIG. 4, the generation of the self-built electric field E may accelerate movement of electrons of the original DSSC, so as to further improve the efficiency.

As seen from the above embodiments, since in the embodiments of the present invention, the CdTe layer may absorb light in a long-wave band which cannot be absorbed by the dye, a large number of electrons may be excited by the CdTe layer and may be provided to the electrolyte, so that an exchanging rate of the redox electron pairs in the electrolyte is increased, and charge loss due to the recombination of the electrons already excited to the TiO₂ conduction band with the electrolyte is efficiently reduced. Thus, the conversion efficiency of the DSSC and a current density may be improved efficiently. At the same time, the energy level of the electrolyte may be affected, and the open circuit voltage may be increased, which is equivalent to an “amplification” of the original DSSC photocurrent by a newly added thin film solar battery. Also, when the solar cell of the present invention operates, the self-built potential may be generated inside the solar cell, so as to accelerate transmission of the electrons from the anode to the cathode. Compared with the traditional single DSSC, the DSSC of the present invention significantly suppresses occurrence of a dark reaction, increases the photocurrent density, open circuit voltage, and the utilization of the sunlight, based on enhancement of dye-sensitized reactions.

The significance of the present invention consists in that the very good light excitation characteristic of the CdTe layer may be utilized to generate the electrons for complementing the requirements of the electrolyte redox couple for the electrons. Thus, the electron interception (dark reaction) process may be suppressed, and the dye sensitized process may be accelerated. In addition, another significance of the present invention is in that the self-built electric field may be generated in the thin-film cell, which may just accelerate the movement of the electrons in the original DSSC, and further improve the efficiency. For nearly 15 years, a feasible method is desired, since the improvement on the DSSC could not achieve a significant effect. The present invention overcomes the defect of the single DSSC, which is an innovation in the system level to the traditional DSSC.

The above is only the preferred embodiments of the present invention and the present invention is not limited to the above embodiments. Therefore, any modifications, substitutions and improvements to the present invention are possible without departing from the spirit and scope of the present invention.

1. A solar cell, comprising a cathode component, an anode component, sealant for assembling the cathode component and the anode component to form a closed space, and electrolyte accommodated in the closed space, wherein the cathode component comprises a lower transparent conductive substrate, a nano-oxide semiconductor thin film formed on the lower transparent conductive substrate, and dye attached to a nano-particle surface of the nano-oxide semiconductor thin film; and the anode component comprises an upper transparent conductive substrate, and an anode electrode layer formed on the upper transparent conductive substrate, the nano-oxide semiconductor thin film and the anode electrode layer being arranged opposite to each other and contacting with the electrolyte,
wherein the anode component further comprises a CdTe layer which is patterned to have an opening, and the anode electrode layer is located in the opening of the CdTe layer.

2. The solar cell according to claim 1, wherein the nano-oxide semiconductor thin film comprises a first nano-oxide semiconductor layer and a second nano-oxide semiconductor layer on the first nano-oxide semiconductor layer, the second nano-oxide semiconductor layer and the anode electrode layer being arranged opposite to each other, a radius of the nano-particle in the second nano-oxide semiconductor layer being larger than that in the first nano-oxide semiconductor layer.

3. The solar cell according to claim 1, wherein the nano-oxide semiconductor thin film is made from one selected from the group consisting of TiO₂, ZnO, SnO₂, Nb₂O₅.

4. The solar cell according to claim 1, wherein a thickness of the nano-oxide semiconductor thin film is 1.0-2.0 μm.

5. The solar cell according to claim 1, wherein the radius of the nano-particle in the nano-oxide semiconductor thin film is 80-120 nm.

6. The solar cell according to claim 1, wherein the anode electrode layer is made from one selected from the group consisting of platinum, and graphene.

7. The solar cell according to claim 1, wherein a thickness of the anode electrode layer is 0.2-0.5 μm.

8. The solar cell according to claim 1, wherein the CdTe layer has a shape of a stripe or a grid.

9. The solar cell according to claim 1, wherein the opening in the CdTe layer has a shape of square, rectangle, round, or hexagon.

10. A method of manufacturing a solar cell, comprising steps of:
a) forming a cathode component, the cathode component comprising a lower transparent conductive substrate, a nano-oxide semiconductor thin film formed on the lower transparent conductive substrate, and dye attached to a nano-particle surface of the nano-oxide semiconductor thin film;
b) forming an anode component, the anode component comprising an upper transparent conductive substrate, and an anode electrode layer and a CdTe layer formed on the upper transparent conductive substrate; and
c) assembling the cathode component and the anode component by using sealant to form a closed space; injecting electrolyte into the closed space, so that the nano-oxide semiconductor thin film and the anode electrode layer are arranged opposite to each other and contact with the electrolyte,
wherein the step b) of forming the anode component comprises: patterning the CdTe layer to have an opening; and filing the opening with the anode electrode layer.

11. The method according to claim 10, wherein the step of patterning the CdTe layer to have the opening comprises: depositing the CdTe layer, planarizing the CdTe layer, and etching the CdTe layer to form the opening.

12. The method according to claim 10, wherein the CdTe layer is formed by sputtering, evaporating or electrodepositing in the step of depositing the CdTe layer.

13. The method according to claim 10, wherein the step of filling the opening with the anode electrode layer comprises: depositing the anode electrode layer in the opening of the CdTe layer from an opening portion of a shielding mask, by using the shielding mask aligned with the opening.

14. The method according to claim 10, wherein the step of filling the opening with the anode electrode layer comprises: forming the anode electrode layer in the opening of the CdTe layer by screen printing.

15. The method according to claim 10, wherein the step of forming the cathode component comprises:
forming a first nano-oxide semiconductor layer on the lower transparent conductive substrate, and forming a second nano-oxide semiconductor layer on the first nano-oxide semiconductor layer as the nano-oxide semiconductor thin film, a radius of the nano-particle in the second nano-oxide semiconductor layer being larger than that in the first nano-oxide semiconductor layer.

16. The method according to claim 15, wherein the step of forming a first nano-oxide semiconductor layer comprises:
producing nano-TiO₂ paste by a sol-gel method; printing the nano-TiO₂ paste on a transparent conductive substrate; and baking.

17. The method according to claim 15, wherein the step of forming a second nano-oxide semiconductor layer comprises:
producing nano-TiO₂ paste using TiO₂ particles; printing the nano-TiO₂ paste on a transparent conductive substrate; and baking.

18. The method according to claim 10, wherein the CdTe layer has a shape of a stripe or a grid.

19. The method according to claim 10, wherein the opening in the CdTe layer has a shape of square, rectangle, round, or hexagon.

20. The solar cell according to claim 2, wherein the nano-oxide semiconductor thin film is made from one selected from the group consisting of TiO₂, ZnO, SnO₂, Nb₂O₅.
